(19) United States
(12) Patent Application Publication
(10) Pub. No.: US 2026/0302124 A1
(43) Pub. Date: Oct. 1, 2026

(54) ION SOURCE AND ION IMPLANTER HAVING ION SOURCE

(71) Applicant: NISSIN ION EQUIPMENT CO., LTD., Koka-city (JP)

(72) Inventors: Sami K. HAHTO, Nashua, NH (US); George SACCO, Groveland, MA (US)

(73) Assignee: NISSIN ION EQUIPMENT CO., LTD., Koka-city (JP)

(21) Appl. No.: 19/696,047

(22) Filed: Jun. 2, 2026

Related U.S. Application Data
(63) Continuation-in-part of application No. 18/621,274, filed on Mar. 29, 2024.

(51) Int. Cl. H01J 37/08; H01J 37/317

(52) U.S. Cl. CPC H01J 37/08; H01J 37/3171

(57) ABSTRACT

An ion source includes a vaporizer that produces a vapor from a solid raw material, and a plenum including a plenum chamber having a first wall through which the vaporizer is in fluid communication with an interior of the plenum chamber, and a second wall opposite the first wall. The second wall includes a plenum plate with a longitudinal aperture therein.

### CROSS-REFERENCE TO RELATED APPLICATION

This application is a Continuation-In-Part Application of U.S. application Ser. No. 18/621,274, filed on Mar. 29, 2024, the disclosure of which being incorporated by reference herein in its entirety.

### BACKGROUND

The present disclosure relates to an ion source and, in particular, an ion source having a plenum chamber and plenum plate with longitudinal aperture, and an ion implanter having the same.

Ion sources generate a plasma from which an ion beam is extracted. The extracted ion beam is then directed onto a target, e.g., a wafer, in order to implant various ions into the target to dope the target with the ions.

The ion beam may be a spot beam or a ribbon ion beam. A spot beam has an elliptical cross-section when the ion beam is cut in a plane perpendicular to a traveling direction of the ion beam. A ribbon beam has a rectangular cross-section (i.e., a vertical length that is greater than a horizontal length) when the ion beam is cut in a plane perpendicular to the traveling direction of the ion beam. In either case, it is advantageous for the ion source to produce a plasma from which a uniform ion beam may be extracted to efficiently implant the ions into the target.

### SUMMARY

It is an aspect to provide a ion source which achieves improved uniformity of the plasma when generating a ribbon ion beam.

According to an aspect of one or more embodiments, an ion source may comprise a vaporizer comprising a nozzle; a plenum comprising a plenum chamber having a first wall through which the nozzle extends and a second wall opposite the first wall that comprises a plenum plate; and an ionization chamber. The plenum plate separates the plenum chamber from the ionization chamber, and the plenum plate comprises one or more openings in a longitudinal direction.

According to another aspect of one or more embodiments, an ion source may comprise a vaporizer comprising a nozzle; a plenum chamber having a first wall through which the nozzle extends and a second wall opposite to the first wall, the first wall and the second wall defining an interior space in which a vapor from the vaporizer spreads out from the nozzle; and an ionization chamber. A plenum plate forms the second wall of the plenum chamber and separates the plenum chamber from the ionization chamber, and the plenum plate comprises one or more openings in a longitudinal direction through which the plenum chamber is in fluid communication with the ionization chamber.

### BRIEF DESCRIPTION OF THE DRAWINGS

The above and/or other aspects will become apparent and more readily appreciated from the following description of various embodiments, taken in conjunction with the accompanying drawings, in which:

FIG. 1 is a schematic plan view of an example of an ion implanter, according to some embodiments;

FIG. 2 illustrates an exploded perspective view of an example of a ion source of the ion implanter, according to some embodiments;

FIGS. 3-5 illustrate a ion source, according to some embodiments, in which FIG. 3 illustrates the ion source when viewed from a Z-axis direction, FIG. 4 illustrates a cross-sectional view of the ion source taken along A-A′ in FIG. 3, and FIG. 5 illustrates a cross-sectional view of the ion source taken along B-B′ in FIG. 3;

FIGS. 6-8 illustrate a ion source, according to some embodiments, in which FIG. 6 illustrates the ion source when viewed from a Z-axis direction, FIG. 7 illustrates a cross-sectional view of the ion source taken along A-A′ in FIG. 6, and FIG. 8 illustrates a cross-sectional view of the ion source taken along B-B′ in FIG. 6;

FIG. 9 illustrates an example of a nozzle of a vaporizer of the ion source, according to some embodiments.

FIG. 10 illustrates an example of a heater of the ion source, according to some embodiments;

FIGS. 11-13 illustrate a liner of the ion source, according to some embodiments, in which FIG. 11 illustrates the liner when the ion source is viewed from a Z-axis direction in FIG. 2, FIG. 12 illustrates a cross-sectional view of the liner taken along A-A′ in FIG. 11, and FIG. 13 illustrates a cross-sectional view of the liner taken along B-B′ in FIG. 11;

FIGS. 14-16 illustrate a liner of the ion source, according to some embodiments, in which FIG. 14 illustrates the liner when the ion source is viewed from a Z-axis direction in FIG. 2, FIG. 15 illustrates a cross-sectional view of the liner taken along A-A′ in FIG. 14, and FIG. 16 illustrates a cross-sectional view of the liner taken along B-B′ in FIG. 14;

FIGS. 17-18 illustrate an ion source, according to some embodiments, in which FIG. 17 illustrates the ion source when viewed from a Z-axis direction, and FIG. 18 illustrates a cross-sectional view of the ion source taken along A-A′ in FIG. 17;

FIGS. 19-20 illustrate an ion source, according to some embodiments, in which FIG. 19 illustrates the ion source when viewed from a Z-axis direction, and FIG. 20 illustrates a cross-sectional view of the ion source taken along A-A′ in FIG. 19;

FIGS. 21-22 illustrate a liner of an ion source, according to some embodiments, in which FIG. 21 illustrates the liner when the ion source is viewed from a Z-axis direction, and FIG. 22 illustrates a cross-sectional view of the liner taken along A-A′ in FIG. 21;

FIGS. 23-24 illustrate a liner of an ion source, according to some embodiments, in which FIG. 23 illustrates the liner when the ion source is viewed from a Z-axis direction, and FIG. 24 illustrates a cross-sectional view of the liner taken along A-A′ in FIG. 23; and

FIGS. 25-27 illustrate an ion source, according to some embodiments, in which FIG. 25 illustrates the ion source when viewed from a Z-axis direction, FIG. 26 illustrates a cross-sectional view of the ion source taken along A-A′ in FIG. 25, and FIG. 27 illustrates a cross-sectional view of the ion source taken along B-B′ in FIG. 25.

### DETAILED DESCRIPTION

In a related art ion source, one or more gases and/or vapors are injected into a plasma chamber of the ion source to generate the plasma inside the plasma chamber. In a related art technology, a plenum is used to generally distribute the gas or vapor throughout an arc chamber. However, the plenum in the related art technology is used to distribute gases or vapor to produce an efficient reaction with a filament, and does not take into account properties of the ion beam. For example, the related art technology does not take into account differences between plasma generated to produce a spot beam verses a ribbon ion beam. In particular, in the case of a ribbon ion beam, it is advantageous for the one or more gases and/or vapors to be uniformly dispersed longitudinally within a plasma chamber so that a plasma density is uniform in a longitudinal direction within the plasma chamber in order to be able to extract a consistent ribbon ion beam to effectively dope the target.

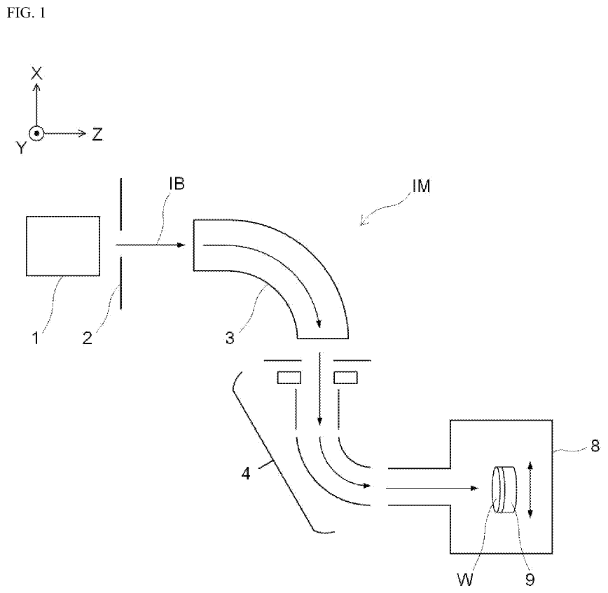

FIG. 1 is a schematic plan view of an example of an ion implanter IM, according to some embodiments. The ion implanter IM illustrates an example of a use case of the ion source. The ion implanter IM is only an example and, in some embodiments, the ion source may be used in any device requiring ion generation.

In an embodiment, the ion implanter IM may include a ion source 1, one or more extraction electrodes 2, a mass analyzer 3, an E-bend device 4, a process chamber 8, and a wafer holder 9. However, these components are only an example and, in some embodiments, a greater or lesser number of components may be included in the ion implanter IM.

In an embodiment, the ion source 1 may be an indirect hot cathode (IHC) ion source. However, embodiments are not limited thereto and, in some embodiments, other types of ion source may be used. In the description that follows, the ion source 1 is described under the assumption that ion source 1 is an IHC ion source. The ion source 1 generates plasma, which is a source of an ion beam IB. The one or more extraction electrodes 2 extract the ion beam IB from the plasma generated in the ion source 1. In some embodiments, the one or more extraction electrodes 2 may include a plurality of extraction electrodes 2.

The ion beam IB extracted from the extraction electrode 2 contains a plurality of ions. The mass analyzer 3, which is an electromagnet, selects the ions according to their mass to extract desired ions from the ion beam IB. The E-bend device 4 accelerates or decelerates and bends the ion beam IB including ions selected by mass analyzer 3 to convert the ion beam IB into an ion beam IB having a desired energy.

The ion beam IB having the desired energy is then irradiated onto a wafer W that is held by a wafer holder 9. By moving the wafer holder 9 (and thus the wafer W) across the ion beam IB, an ion implantation process may be carried out on the wafer W.

The wafer W held by the wafer holder 9 is placed in the process chamber 8. A drive device (not illustrated) is connected to the wafer holder 9. The drive device may adjust a posture of the wafer holder 9 with respect to the ion beam IB to adjust an irradiation angle of the ion beam IB with respect to the wafer W.

The XYZ axes shown in FIG. 1 are drawn such that the Z axis is parallel to the traveling direction of the ion beam IB; the X and Y axes are mutually orthogonal to the Z axis. The direction of each of the XYZ axes for any individual component varies according to an orientation of a component with respect to the ion beam being transported as illustrated in FIG. 1.

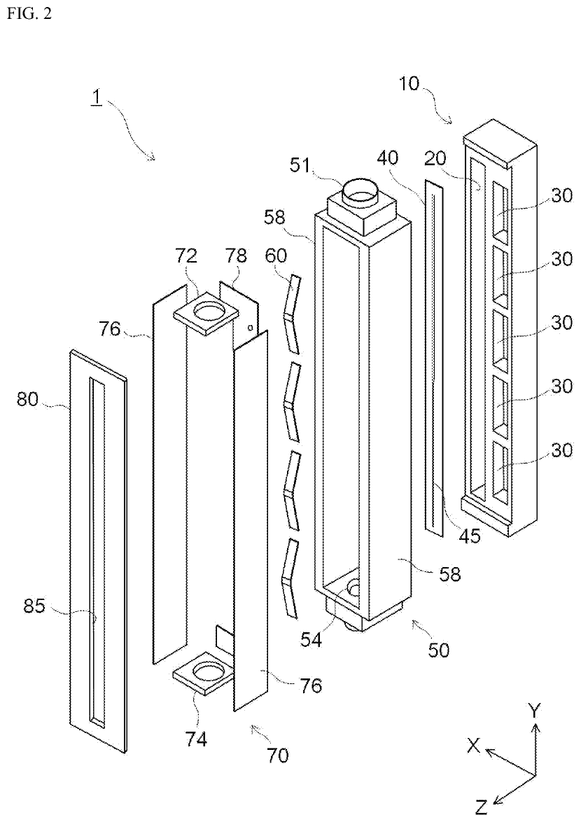

FIG. 2 illustrates an exploded perspective view of an example of a ion source of the ion implanter, according to some embodiments.

As used herein, the term “plenum” refers to a structure that receives a vapor or gas from a source and permits the vapor or gas to spread out uniformly before being distributed. The term “plenum chamber” refers to an interior space within the plenum in which the vapor or gas may spread out uniformly before being distributed.

In an embodiment, the ion source 1 may include a plenum 10 and an ionization chamber 50. The plenum 10 may include a plenum chamber 20, a plurality of gas feed chambers 30, and a plenum plate 40. The plenum chamber 20 is rectangular, having a long side in a vertical direction (e.g., a Y-axis direction) and a short side in a horizontal direction (e.g., a X-axis direction). In other words, the plenum chamber 20 may be a longitudinal chamber having a width in the X-axis direction and height in the Y-axis direction that is greater than the width. In an embodiment, the plenum chamber 20 includes a plurality of walls that, along with the plenum plate 40, define the plenum chamber 20. In an embodiment, the plenum chamber 20 has an opening in a distal side thereof and the opening is covered by the plenum plate 40. The plenum plate 40 has a slit 45 therein. The slit 45 is long in the vertical direction (e.g., the Y-axis direction) and narrow in the horizontal direction (e.g., the X-axis direction) and thus forms a longitudinal aperture in the plenum plate 40. In some embodiments, the plenum plate 40 may have a plurality of holes 42, as described in more detail below. In some embodiments, the plenum plate 40 may have an hourglass-shaped longitudinal aperture 44, as described in more detail below. Examples of the slit 45, the plurality of holes 42, and the hourglass-shaped longitudinal aperture 44 are described in more detail below.

The plurality of gas feed chambers 30 are formed adjacent to the plenum chamber 20. In an embodiment, the plurality of gas feed chambers 30 are spaced apart from each other in the vertical direction (e.g., the Y-axis direction). In an embodiment, each of the gas feed chambers 30 may be generally rectangular, having a long side in a vertical direction (e.g., a Y-axis direction) and a short side in a horizontal direction (e.g., a X-axis direction). Each of the gas feed chambers 30 may have an opening in a distal end thereof, similar to the plenum chamber 20. In an embodiment, a surface in which the openings of the plurality of gas feed chambers 30 may be formed may be coplanar with the plenum plate 40. In an embodiment, a surface in which the openings of the plurality of gas feed chambers 30 are provided may be coplanar with a surface in which the opening of the plenum chamber 20 is provided.

The embodiment of FIG. 2 shows the plenum 10 as formed from a single block. However, in some embodiments, the plenum 10 may be formed in two separate blocks and the two separate blocks may be fixed together. In other words, the plenum chamber 20 may be formed in a first block and the plurality of gas feed chambers 30 may be formed in a second block, and the first and second blocks may be secured together side-by-side. However, it is advantageous to form the plenum 10 from a single block in terms of decreased manufacturing cost and decreased complexity.

In an embodiment, each of the plenum 10 and the plenum plate 40 may be made of carbon. However, this is only an example and, in other embodiments, each of the plenum 10 and the plenum plate 40 may be made of graphite or other materials.

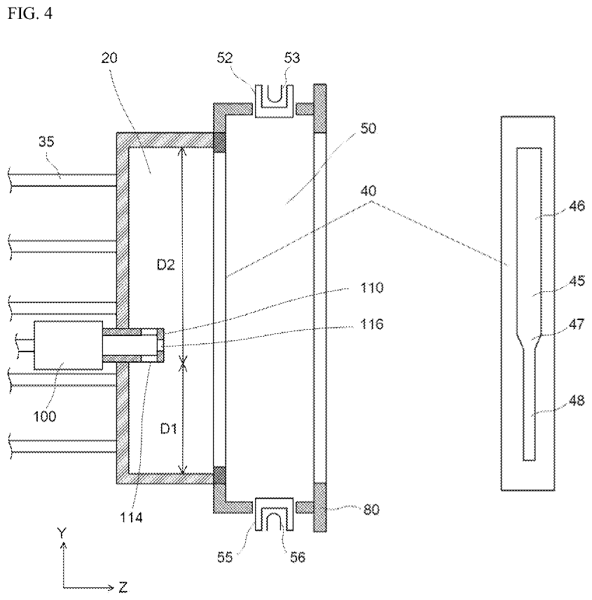

In an embodiment, the ionization chamber 50 may include a top wall 51 including a top hole for receiving a cathode 52 and a filament 53 (see FIG. 4), a bottom wall 54 including a bottom hole for receiving a cathode 55 and a filament 56 (see FIG. 4), and two side walls 58 that connect the top wall to the bottom wall. The front and the back of the ionization chamber 50 in a third direction (e.g., a Z-axis direction), which is a traveling direction of an ion beam that is extracted from the ion source 1, are open. The ionization chamber 50 is rectangular, having a long side in a vertical direction (e.g., a Y-axis direction) and a short side in a horizontal direction (e.g., a X-axis direction). In other words, similar to the plenum chamber 20, the ionization chamber 50 may be a longitudinal chamber having a width in the X-axis direction and height in the Y-axis direction that is greater than the width. It is noted that the cathode 52 and the filament 53 are described as being received in the top hole of the ionization chamber 50 and the cathode 55 and filament 56 are described as being received in the bottom hole of the ionization chamber 50 in FIG. 1. However, this is only an example and, in some embodiments, the positions of the cathode 52 and the filament 53, and the cathode 55 and the filament 56 may be changed.

The ionization chamber 50 is secured to the plenum 10 at a proximal end of the ionization chamber 50 and a distal end of the ionization chamber 50 is covered by an extraction plate 80. In other words, the back of the ionization chamber 50 is secured to the plenum 10 such that an interior of the plenum chamber 20 is in fluid communication with an interior of the ionization chamber 50 and such that an interior of each of the plurality of gas feed chambers 30 is in fluid communication with the interior of the ionization chamber 50. The front of the ionization chamber 50 is covered by the extraction plate 80. The extraction plate 80 has an extraction aperture 85 therein. The extraction aperture 85 is long in the vertical direction (e.g., the Y-axis direction) and narrow in the horizontal direction (e.g., the X-axis direction) and thus forms a longitudinal aperture in the extraction plate 80. In an embodiment, the extraction aperture 85 has a uniform width along the vertical direction (e.g., Y-axis direction) thereof.

In some embodiments, interior walls of the ionization chamber 50 may be covered by a liner 70. In some embodiments, the liner 70 may include a plurality of liners. The plurality of liners may include a top liner 72, a bottom liner 74, and two side wall liners 76, which correspond respectively to the top wall 51, bottom wall 54, and two side walls 58 of the ionization chamber 50, and a rear liner 78. The rear liner 78 is formed with an opening corresponding to the slit 45 in the plenum plate 40 and openings corresponding to the plurality of gas feed chambers 30. In some embodiments, the plurality of liners may further include a front liner that is formed with an opening corresponding to the extraction aperture 85 in the extraction plate 80. Examples of the liner 70 will be described in more detail below.

In an embodiment, the liner 70 may be held in place by a spring 60. In an embodiment, the spring 60 may include a plurality of leaf springs as illustrated in the example of FIG. 1. However, this is only an example and, in some embodiments, the spring 60 may include a plurality of coil springs.

In some embodiments, the liner 70 may be omitted.

In use, the plenum chamber 20 receives a vapor from a single point source and provides a space for the vapor to spread out evenly along the height of the ion source 1. In other words, the vapor may broaden and diverge in a longitudinal direction (e.g., a Y-axis direction) within the plenum chamber 20. The plenum plate 40 restricts the flow of vapor from the single point source. The shape of the slit 45 is a longitudinal aperture and is used to produce vertical uniformity of the flow of the vapor into the ionization chamber 50. Each of the plurality of gas feed chambers 30 receives a gas from one or more of a plurality of gas feed lines 35 (not illustrated in FIG. 2) and allows the received gas to spread out before entering the ionization chamber 50. In the ionization chamber 50, a plasma based on the vapor and the gases is generated and the ion beam IB is extracted by the extraction electrodes 2 outside the extraction plate 80 of the ionization chamber 50. The liner 70 prevents sputtering of a plasma generated in the ionization chamber 50 onto the walls of the ionization chamber 50, and thus may increase the time needed between cleanings of the ionization chamber 50, thus saving maintenance costs. In some embodiments, the liner 70 may prevent reaction of the plasma with the walls of the ionization chamber 50.

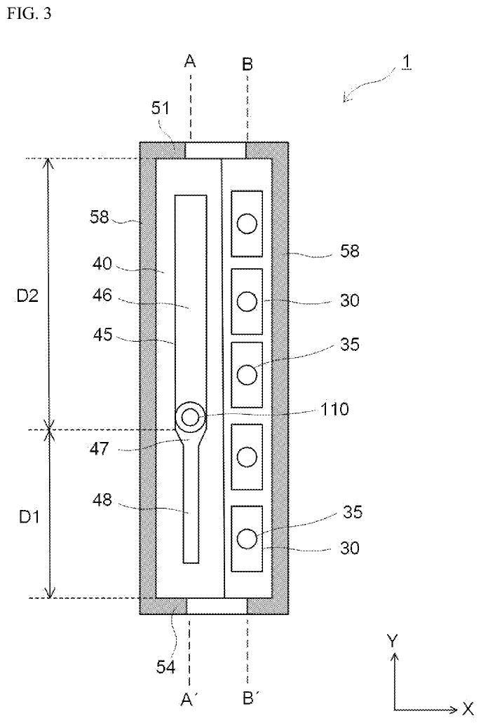

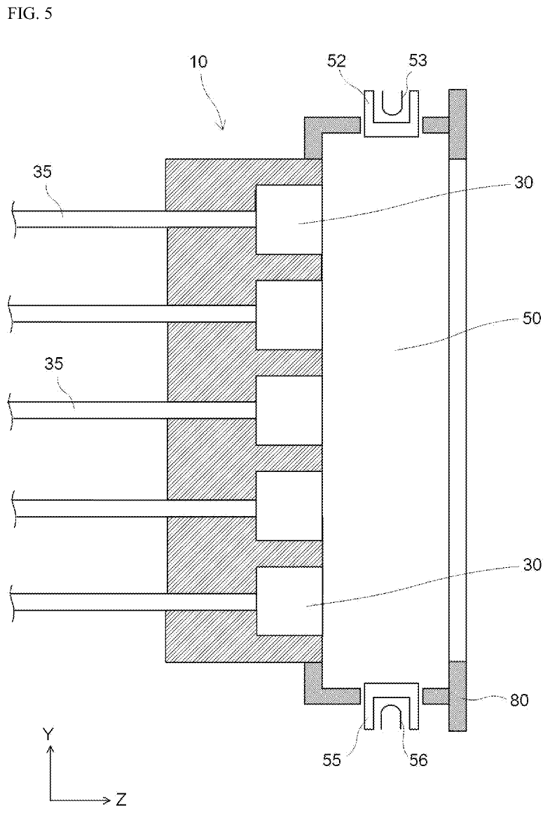

FIGS. 3-5 illustrate the ion source 1, according to some embodiments, in which FIG. 3 illustrates the ion source 1 when viewed from a Z-axis direction with the extraction plate 80 removed, FIG. 4 illustrates a cross-sectional view of the ion source 1 taken along A-A′ in FIG. 3, and FIG. 5 illustrates a cross-sectional view of the ion source 1 taken along B-B′ in FIG. 3. In FIGS. 3-5, like reference designators represent like components in FIG. 2 that have like structure and functions, and therefore a repeated description thereof is omitted for conciseness.

As illustrated in FIGS. 3-5, in an embodiment, the plenum 10 includes the plurality of gas feed chambers 30, each having a corresponding gas feed line 35. In other words, the plurality of gas feed lines 35 feed gases respectively into corresponding ones of the plurality of gas feed chambers 30. The gas feed lines 35 feed various gases into the ionization chamber 50 for generating the plasma in the ionization chamber 50. For example, in some embodiments, the gases may include tungsten fluoride (WF6), hydrogen (H2) co-gas, boron trifluoride (BF3), arsine (AsH3), phosphine (PH3), a noble gas such as Argon, Helium and Xenon and/or chlorine (Cl2), etc. However, these are only examples and, in some embodiments, any gas suitable for generating plasma may be used.

In an embodiment, the ion source 1 includes a vaporizer 100 for generating the vapor, and a nozzle 110 for introducing the vapor into the plenum chamber 20. The vaporizer 100 may be, for example, a vaporizer as described in U.S. application Ser. No. 18/585,499, filed Feb. 23, 2024, and titled “VAPORIZER AND ION SOURCE”; U.S. patent application Ser. No. 17/714,491, filed Apr. 6, 2022, now U.S. Patent Application Publication No. 2023/326702 for “VAPORIZER, ION SOURCE AND METHOD FOR GENERATING ALUMINUM-CONTAINING VAPOR”; or U.S. patent application Ser. No. 17/945,705, filed Sep. 15, 2022 for “VAPORIZER, ION SOURCE AND METHOD FOR GENERATING ALUMINUM-CONTAINING VAPOR”, the entire contents of each of these U.S. patent applications being herein incorporated by reference in their entireties. In some embodiments, the vaporizer 100 may generate the vapor from a solid raw material. For example, in some embodiments, the solid raw material may be aluminum (Al). However, this is only an example and, in some embodiments, other solid raw materials may be used depending on the vapor used to generate the plasma for extracting the ion beam. In some embodiments, the vaporizer 100 may generate the vapor from antinomy (Sb), sulfur(S) containing compounds, InI3, InCl3, WCl4, Al2O3, AlCl3, Ti (Titanium), Ni (Nickel), or molybdenum disulfide (MoS2) alone or in combination with one or more gasses. However, these are only examples and, in some embodiments, the vaporizer 100 may generate the vapor from other materials and/or gasses.

An interior of the vaporizer 100 may be in fluid communication with the interior of the plenum chamber 20 through the nozzle 110. The nozzle 110 of the vaporizer extends through a wall the plenum chamber 20 that is opposite from the plenum plate 40 in the Z-axis direction, and thus a distal portion of the nozzle 110 may extend into the plenum chamber 20.

In the ion source 1 illustrated in FIGS. 3-5, an odd number of the plurality of gas feed chambers 30 are included in the ion source 1. In this case, the vaporizer 100 is offset from the center of the wall of the plenum chamber 20 in the Y-axis direction. The vaporizer 100 may be offset from the center to allow for the gas feed lines 35 to be uniformly spaced along the longitudinal direction (e.g., the Y-axis direction). In other words, the vaporizer 100 may be offset so as not to conflict with one of the gas feed lines 35.

In some embodiments, the ion source 1 may include five gas feed chambers 30 and five gas feed lines 35 as illustrated in FIGS. 3-5. In this case, the vaporizer 100 may be disposed such that two gas feed lines 35 are disposed below the vaporizer 100 and three gas feed lines 35 are disposed above the vaporizer 100 in the Y-axis direction.

The slit 45 of the plenum plate 40 has a geometry based on the location of the nozzle 110 of the vaporizer 100 in the wall of the plenum chamber 20 in the longitudinal direction (e.g., the Y-axis direction). In an embodiment, the slit 45 may include a top portion 46, a transition portion 47, and a bottom portion 48. The top portion 46 has a width in the X-axis direction that is wider than a width of the bottom portion 48 in the X-axis direction. A width of the transition portion 47 in the X-axis direction gradually narrows from the top portion 46 to the bottom portion 48. A location of the nozzle 110 of the vaporizer 100 in the wall of the plenum chamber 20 in the longitudinal direction generally coincides with a location of the transition portion 47 in the slit 45 in the longitudinal direction. In an embodiment, a bottom of the nozzle 110 may be located at a position in the wall of the plenum chamber 20 in the longitudinal direction that corresponds to a top of the transition portion in the longitudinal direction (best seen in FIG. 3). In an embodiment, a distance D1 of the bottom of the nozzle 110 of the vaporizer 100 from a bottom wall of the plenum chamber 20 may correspond to a combined length of the bottom portion 48 and the transition portion 47 of the slit 45 in the Y-axis direction. In an embodiment, a distance D2 of the bottom of the nozzle 110 from a top wall of the plenum chamber 20 may correspond to a distance from the top wall of the plenum chamber 20 to a bottom of the transition portion 47 of the slit 45 in the Y-axis direction. Since the location of the vaporizer 100 is offset from a center of the plenum chamber 20 in the Y-axis direction, the distance D2 from the top wall of the plenum chamber 20 is greater than the distance D1.

In an embodiment, the length in the longitudinal direction of the portion of the slit 45 that has the narrower width may be shorter than a length in the longitudinal direction of the portion of the slit 45 that has the wider width. Thus, assuming a case in which the vaporizer 100 is disposed so as to be offset in the direction of the top wall of the plenum chamber 20 such that two gas feed lines 35 are disposed on top of the vaporizer 100 and three gas feed lines are disposed on the bottom of the vaporizer 100 (i.e., opposite to the example illustrated in FIGS. 3-5), the top portion 46 of the slit 45 would have a narrower width that the bottom portion 48 of the slit 45 (again opposite to the example illustrated in FIGS. 3-5) and the width of the transition portion 47 would gradually decrease from the bottom portion 48 to the top portion 46 (i.e., in the opposite direction to that illustrated in FIGS. 3-5). This configuration is due to the volume of the plenum chamber 20 being less on the side to which the vaporizer 100 is offset such that the portion of the plenum plate 40 with the narrower slit restricts the flow of vapor into the ionization chamber 50 more than the portion of the plenum plate 40 with the wider slit in order that the vapor flows more uniformly into the ionization chamber 50. With the flow of a more uniform vapor along the longitudinal (e.g., the Y-axis direction) into the ionization chamber 50, a more uniform plasma may be generated in the ionization chamber 50 and thus a more uniform ribbon ion beam IB may be extracted from the ionization chamber 50.

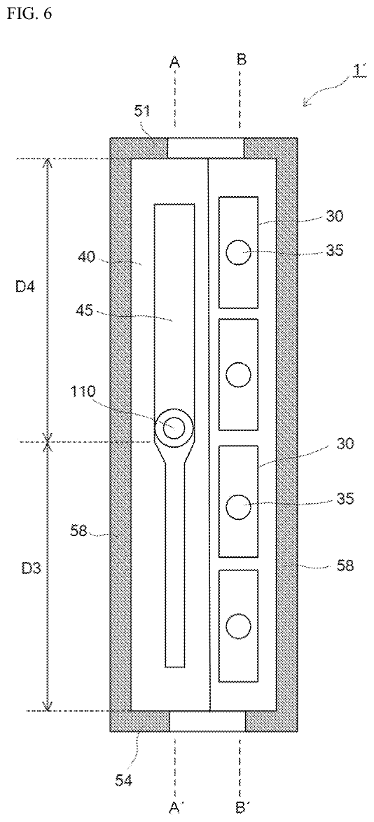

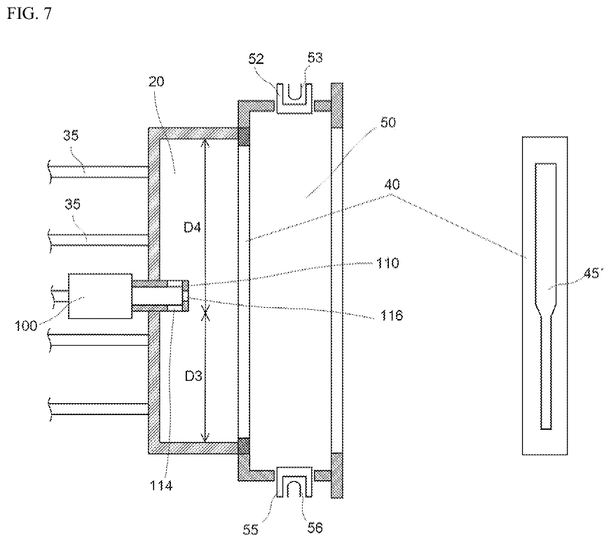

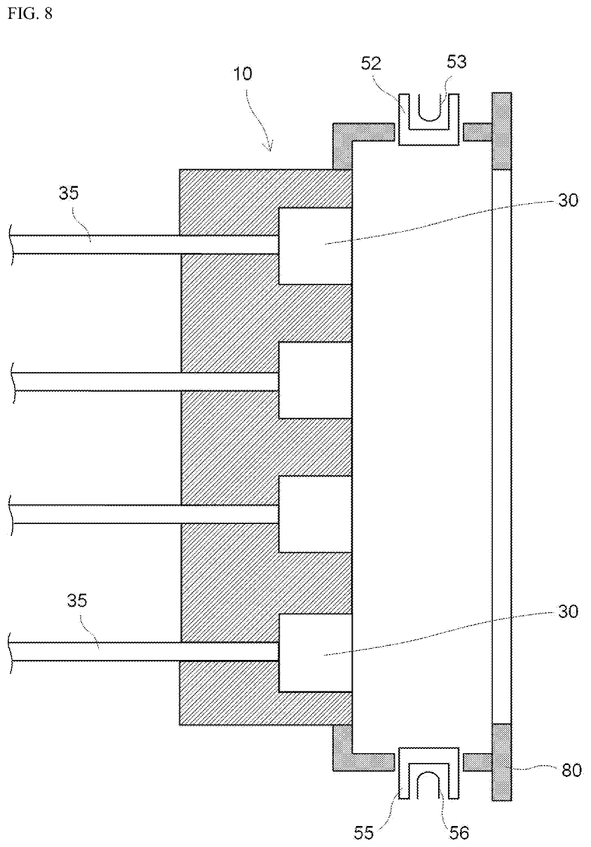

FIGS. 6-8 illustrate a ion source 1′, according to some embodiments, in which FIG. 6 illustrates the ion source 1′ when viewed from a Z-axis direction, FIG. 7 illustrates a cross-sectional view of the ion source 1′ taken along A-A′ in FIG. 6, and FIG. 8 illustrates a cross-sectional view of the ion source 1′ taken along B-B′ in FIG. 6. In FIGS. 6-8, like reference designators represent like components in FIGS. 2-5 that have like structures and functions, and therefore a repeated description thereof is omitted for conciseness.

FIGS. 6-8 illustrate an example in which the plurality of gas feed chambers 30 and the plurality of gas feed lines 35 are each provided in an even number. In this configuration, the vaporizer 100 may be disposed to feed vapor into the plenum chamber 20 at the center of the wall of the plenum chamber 20. For example, FIGS. 6-8 illustrate an example of the ion source 1′ in which four gas feed chambers 30 and four gas feed lines 35 are provided and two of the gas feed lines 35 are positioned above the vaporizer 100 and two of the gas feed lines 35 are positioned below the vaporizer 100. In this case, the nozzle 110 of the vaporizer 100 may be located in the center of the wall of the plenum chamber 20 in the Y-axis direction.

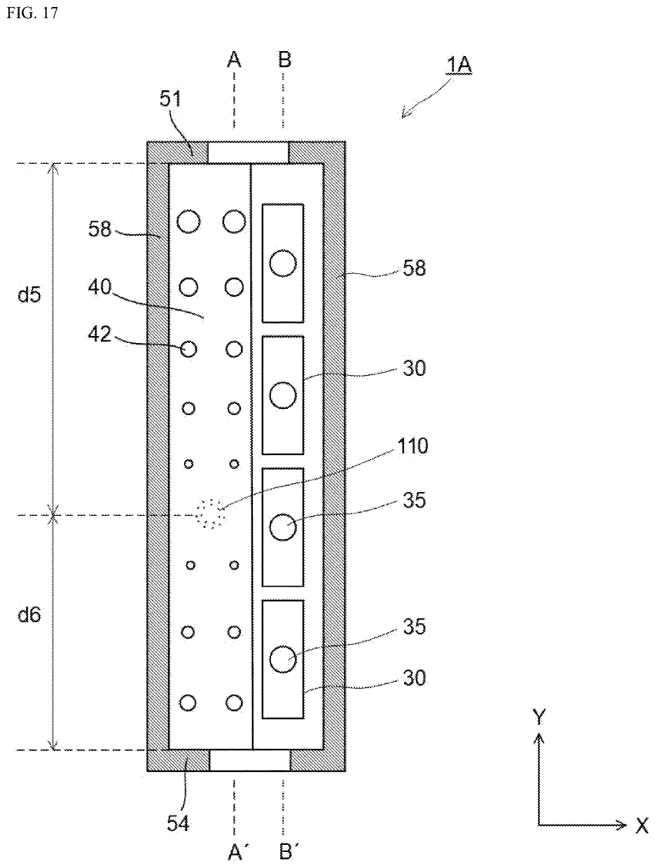

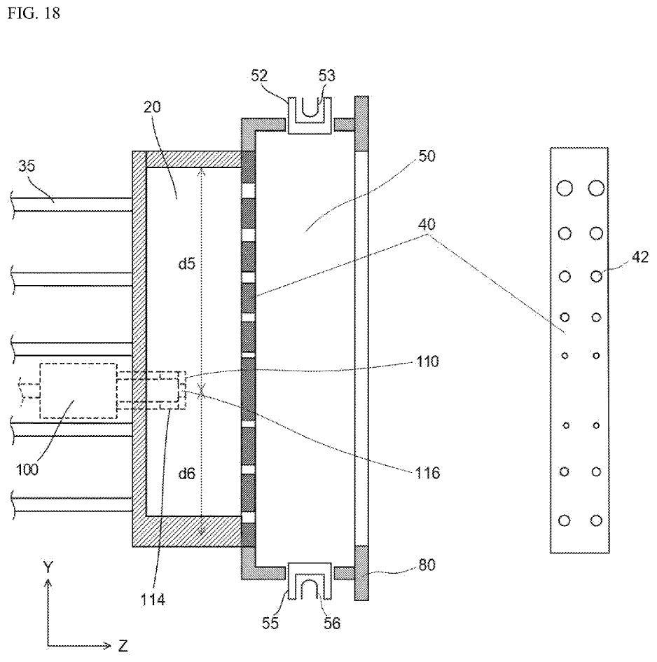

In an embodiment, similar to the example illustrated in FIGS. 3-5, a location of the nozzle 110 of the vaporizer 100 in the wall of the plenum chamber 20 in the longitudinal direction may generally coincide with a location of the transition portion 47 in the longitudinal direction of the slit 45. In an embodiment, a distance D3 of the bottom of the nozzle 110 of the vaporizer 100 from a bottom wall of the plenum chamber 20 may correspond to a combined length of the bottom portion 48 and the transition portion 47 of the slit 45 in the Y-axis direction. In an embodiment, a distance D4 of the bottom of the nozzle 110 from a top wall of the plenum chamber 20 may correspond to a distance from the top wall of the plenum chamber 20 to a bottom of the transition portion 47 of the slit 45 in the Y-axis direction. While, in this example, the location of the vaporizer 100 is at the center of the plenum chamber 20 in the Y-axis direction, the bottom of the nozzle 110 is located below the center and thus the distance D4 from a top wall of the plenum chamber 20 is still greater than the distance D3. FIGS. 17-18 illustrate an ion source 1A, according to some embodiments, in which FIG. 17 illustrates the ion source 1A when viewed from a Z-axis direction with the extraction plate 80 removed, and FIG. 18 illustrates a cross-sectional view of the ion source 1A taken along A-A′ in FIG. 17. In FIGS. 17-18, like reference designators represent like components in FIGS. 2-5 that have like structures and functions, and therefore a repeated description thereof is omitted for conciseness.

In the ion source 1A illustrated in FIGS. 17-18, the nozzle 110 of the vaporizer 100 is positioned below a longitudinal center of the wall of the plenum chamber 20 in the Y-axis direction. In the nozzle configuration illustrated in FIGS. 17-18, the plenum plate 40 includes a plurality of holes 42 rather than a continuous slit 45. The plurality of holes 42 may be arranged in a longitudinal direction (e.g., the Y-axis direction) along the plenum plate 40. The plurality of holes 42 may be arranged in the plenum plate 40 in two columns as illustrated. However, the number of columns is not particularly limited and, in some embodiments, one column or more than two columns may be provided. Additionally, in the example illustrated in FIGS. 17-18, eight holes 42 are arranged in the plenum plate 40 in each column. However, the number of holes 42 is not limited thereto and, in some embodiments, more than eight or fewer than eight may be provided in each column.

In an embodiment, a distance d5 of an upper portion of the plenum plate 40 from a top of the plenum plate 40 to a position of the plenum plate 40 that corresponds to a position of a center of the nozzle 110 in the plenum chamber 20 may be greater than a distance d6 of a lower portion of the plenum plate 40 from a bottom of the plenum plate 40 to the position of the plenum plate 40 that corresponds to the position of the center of the nozzle 110 in the plenum chamber 20. In other words, when the nozzle 110 is disposed below a center of the plenum chamber 20, the distances d5 and d6 may satisfy a relationship d5>d6.

In an embodiment, the plurality of holes 42 may have diameters that progressively increase from a region of the plenum plate 40 that corresponds to a location of the center of the nozzle 110 in the plenum chamber 20 toward both longitudinal ends of the plenum plate 40. In other words, holes 42 located closer to the region of the plenum plate 40 that corresponds to the position of the nozzle 110 in the plenum chamber 20 may have smaller diameters than holes 42 located farther from the region of the plenum plate 40 that corresponds to the position of the nozzle 110. This expanding aperture configuration compensates for the higher vapor concentration in the plenum chamber 20 near the nozzle 110 and promotes uniform vapor distribution along the longitudinal direction of the plenum chamber 20 such that the vapor is more uniformly provided through the plenum plate 40 and thus into the ionization chamber 50. In other words, the vapor may spread out within the interior space within the plenum chamber 20 before passing through the plenum plate 40 and into the ionization chamber 50.

Moreover, since the distance d5 is greater than the distance d6, the number of holes 42 provided above the region of the plenum plate 40 that corresponds to the position of the nozzle 110 may be greater than the number of holes 42 provided below the region of the plenum plate 40 that corresponds to the position of the nozzle 110. In the example illustrated in FIGS. 17-18, each of the two columns may have five of the holes 42 provided in the plenum plate 40 above the region of the plenum plate 40 that corresponds to the position of the nozzle 110 and may have three of the holes 42 provided in the plenum plate 40 below the region of the plenum plate 40 that corresponds to the position of the nozzle 110. However, this configuration is only an example and, in some embodiments, the number of the holes 42 in the upper portion of the plenum plate 40 may be more of less than five and the number of holes 42 in the lower portion of the plenum plate 40 may be more or less than three.

In the example illustrated in FIGS. 17-18, the ion source 1A includes an even number of gas feed chambers 30 (e.g., four gas feed chambers), with the nozzle 110 positioned to correspond roughly to a position of the gas feed chamber 30 that is second from the bottom of the ion source 1A. The plurality of holes 42 in the plenum plate 40 provide multiple discrete openings for vapor flow, which may optimize vapor distribution compared to a single continuous slit.

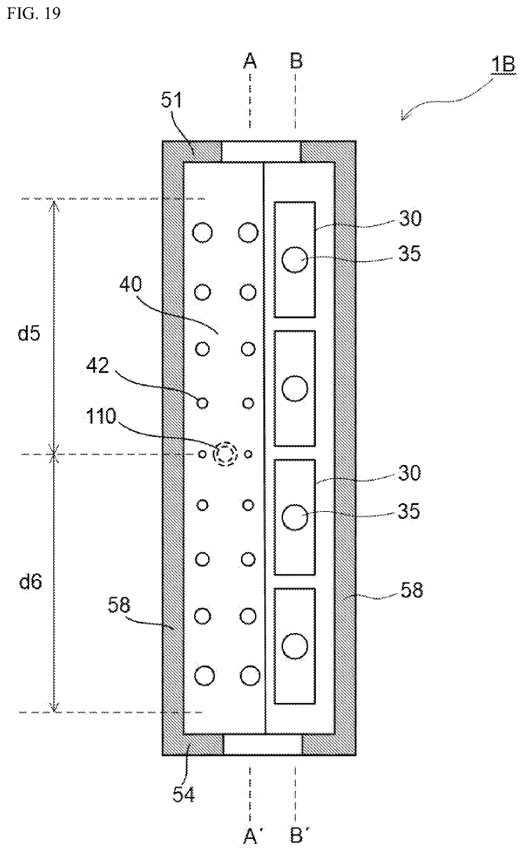

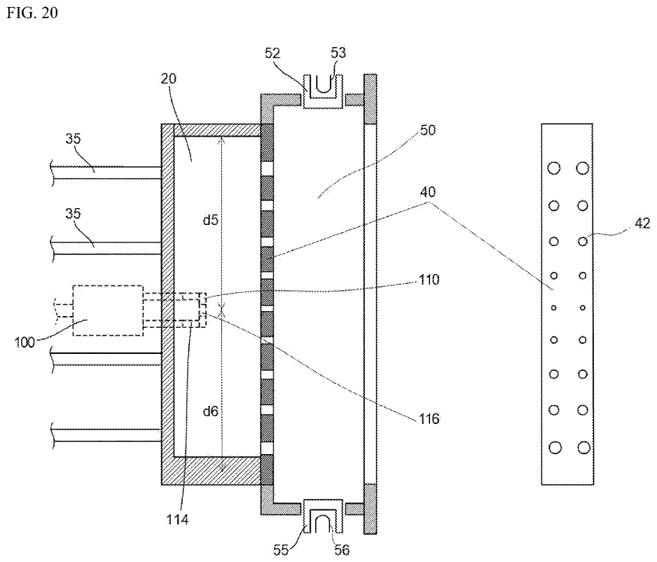

FIGS. 19-20 illustrate an ion source 1B, according to some embodiments, in which FIG. 19 illustrates the ion source 1B when viewed from a Z-axis direction, and FIG. 20 illustrates a cross-sectional view of the ion source 1B taken along A-A′ in FIG. 19. In FIGS. 19-20, like reference designators represent like components in FIGS. 6-8 and 17-18 that have like structures and functions, and therefore a repeated description thereof is omitted for conciseness.

FIGS. 19-20 illustrate an example in which the plurality of gas feed chambers 30 and the plurality of gas feed lines 35 are each provided in an even number, similar to FIGS. 6-8, and with a plurality of holes 42 similar to FIGS. 17-18, but with a centered nozzle configuration. For example, FIGS. 19-20 illustrate an example of the ion source 1B in which four gas feed chambers 30 and four gas feed lines 35 are provided, with two of the gas feed lines 35 positioned above a position corresponding to the nozzle 110 and two of the gas feed lines 35 positioned below the position corresponding to the nozzle 110. In this case, the nozzle 110 is located at a longitudinal center of the wall of the plenum chamber 20 in the Y-axis direction, and the distance d5 from the top of the plenum plate 40 to a position corresponding to the center of the nozzle 110 is equal to the distance d6 from the bottom of the plenum plate 40 to the position corresponding to the center of the nozzle 110. In other words, when the nozzle 110 is disposed at a center of the plenum chamber 20, the distances d5 and d6 may satisfy a relationship d5=d6.

Similar to the configuration shown in FIGS. 17-18, the plenum plate 40 includes the plurality of holes 42 with diameters that may progressively increase from the position in the plenum plate 40 that corresponds to the position of the nozzle 110 in the plenum chamber 20 toward both longitudinal ends to optimize vapor distribution. In the example illustrated in FIGS. 19-20, each of the two columns may have four of the holes 42 provided in the plenum plate 40 above the region of the plenum plate 40 that corresponds to the position of the nozzle 110 and may have four of the holes 42 provided in the plenum plate 40 below the region of the plenum plate 40 that corresponds to the position of the nozzle 110. Moreover, each of the two columns may have a hole 42 in the plenum plate 40 on either side of the position in the plenum plate 40 that corresponds to the position of the nozzle 110 in the plenum chamber 20. Thus, in the embodiment illustrated in FIGS. 19-20, nine of the holes 42 may be provided in each column. However, this configuration is only an example and, in some embodiments, a total number of the holes 42 may be greater than or less than nine and, in some embodiments, the number of the holes 42 in the upper portion of the plenum plate 40 may be more of less than four and the number of holes 42 in the lower portion of the plenum plate 40 may be more or less than four.

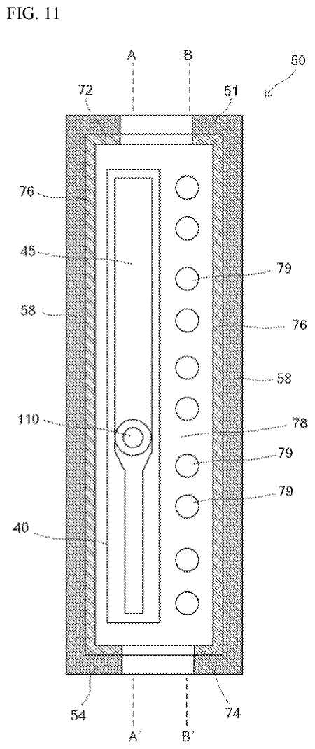

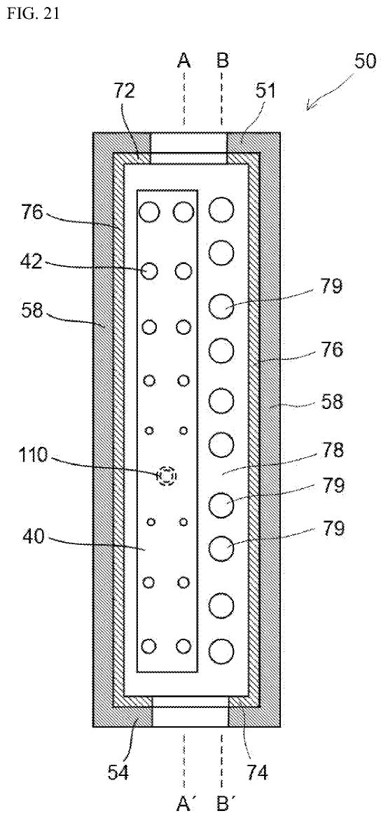

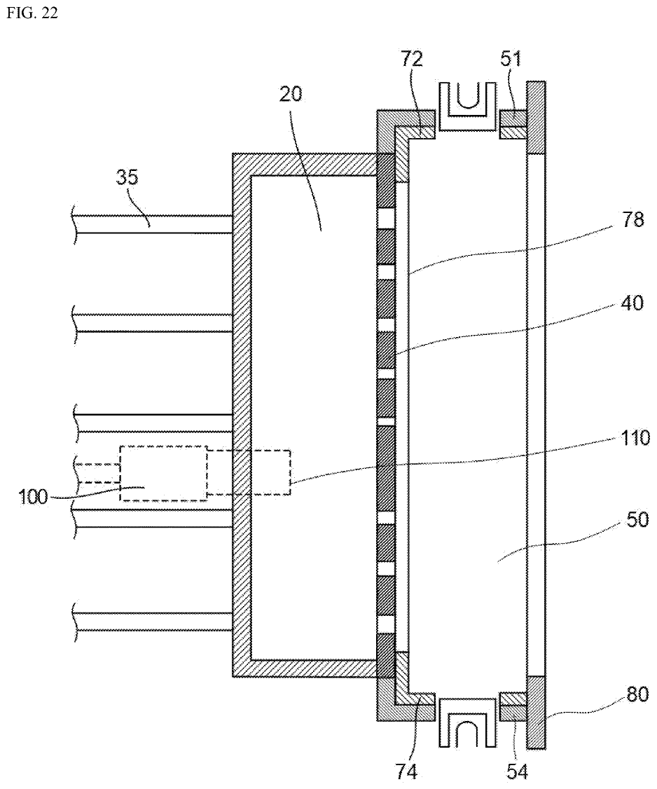

FIGS. 21-22 illustrate a rear line 78 of the liner 70 of the ion source 1A, according to some embodiments, in which FIG. 21 illustrates the liner 70 when viewed from a Z-axis direction, and FIG. 22 illustrates a cross-sectional view of the liner 70 taken along A-A′ in FIG. 21. In FIGS. 21-22, like reference designators represent like components in FIGS. 11-13 and FIGS. 17-18 that have like structures and functions, and therefore a repeated description thereof is omitted for conciseness.

As illustrated in FIG. 21, the rear liner 78 is formed with a plurality of openings corresponding to the plurality of holes 42 in the plenum plate 40 and a plurality of openings 79 that correspond to the plurality of gas feed chambers 30. In the example illustrated in FIGS. 21-22, each gas feed chamber 30 is provided with two openings 79. However, embodiments are not limited thereto and, in some embodiments, the rear liner 78 may have one opening 79 or more than two openings 79 for each of the gas feed chambers 30.

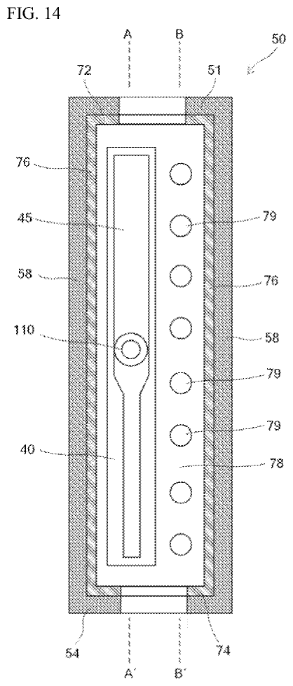

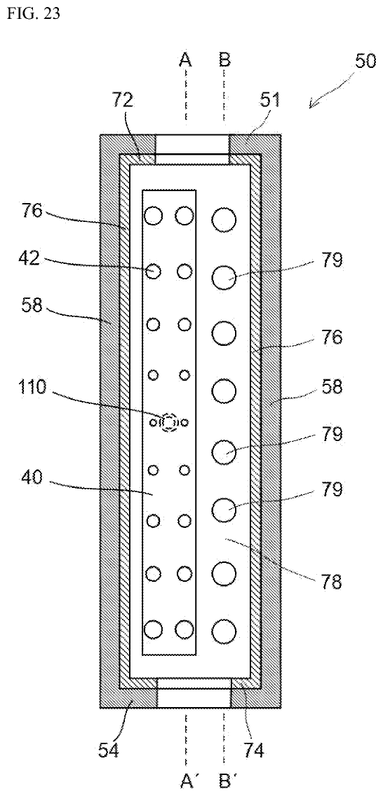

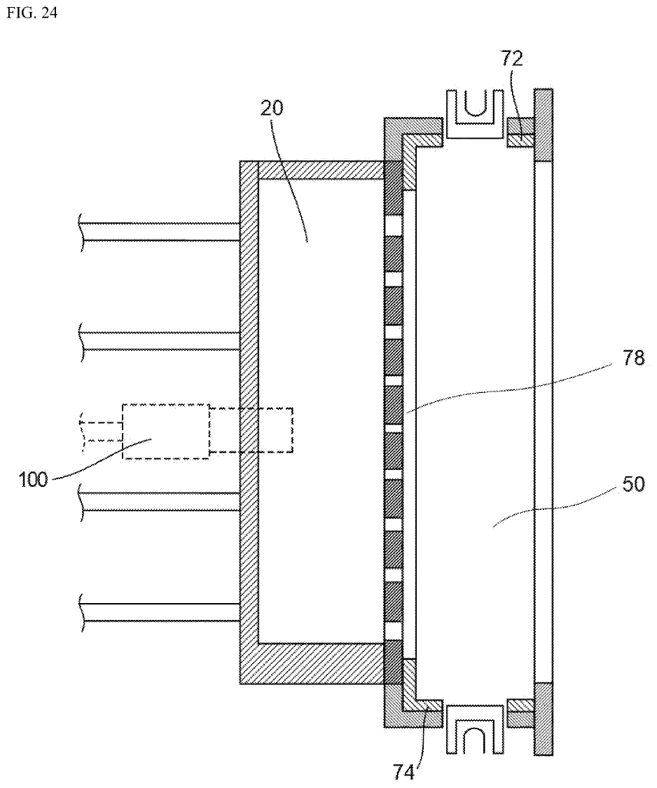

FIGS. 23-24 illustrate a rear liner 78 of the liner 70 of the ion source 1B, according to some embodiments, in which FIG. 23 illustrates the liner 70 when viewed from a Z-axis direction, and FIG. 24 illustrates a cross-sectional view of the liner 70 taken along A-A′ in FIG. 23. In FIGS. 23-24, like reference designators represent like components in FIGS. 14-16 and 19-22 that have like structures and functions, and therefore a repeated description thereof is omitted for conciseness.

In FIGS. 23-24, an example of the rear liner 78 of the liner 70 as applied to the ion source 1B of FIGS. 19-20 is illustrated. As with the example illustrated in FIGS. 21-22, the rear liner 78 includes a plurality of openings corresponding to the plurality of holes 42 in the plenum plate 40 and a plurality of openings 79 corresponding to the plurality of gas feed chambers 30.

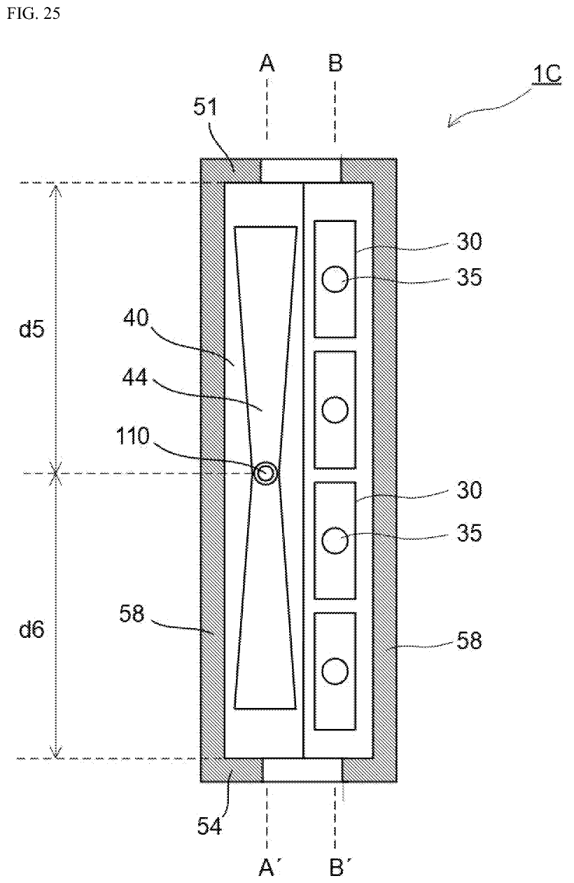

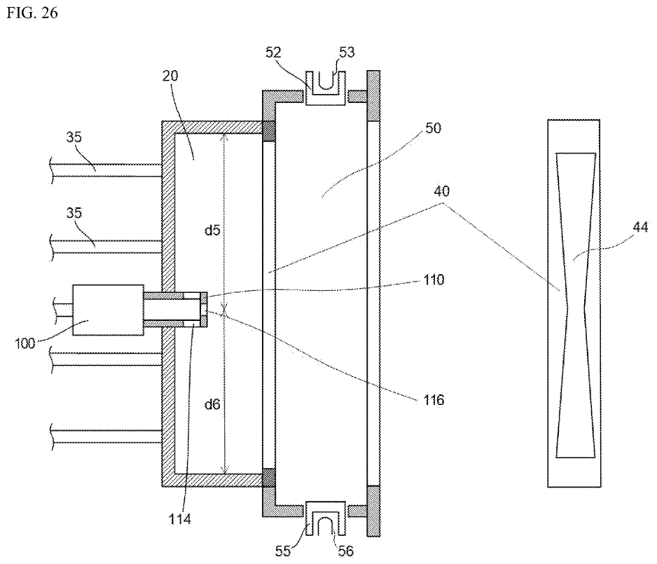

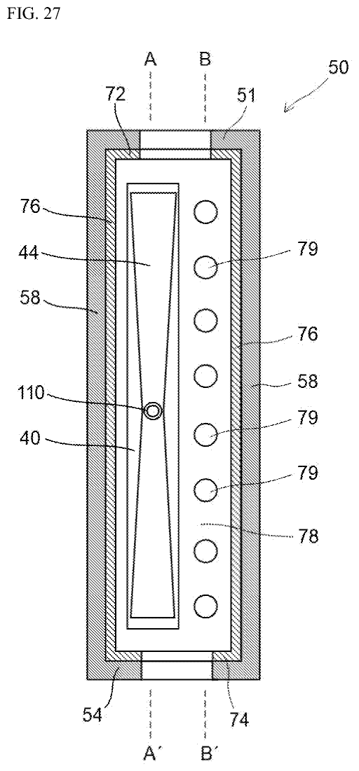

FIGS. 25-27 illustrate an ion source 1C, according to some embodiments, in which FIG. 25 illustrates the ion source 1C when viewed from a Z-axis direction, FIG. 26 illustrates a cross-sectional view of the ion source 1C taken along A-A′ in FIG. 25, and FIG. 27 illustrates a cross-sectional view of the ion source 1C taken along B-B′ in FIG. 25. In FIGS. 25-27, like reference designators represent like components in FIGS. 6-8 that have like structures and functions, and therefore a repeated description thereof is omitted for conciseness.

In the ion source 1C illustrated in FIGS. 25-27, the plenum plate 40 includes a longitudinal aperture 44. The longitudinal aperture 44 may also be referred to as a slit. The longitudinal aperture 44 of FIGS. 25-27 may have an hourglass shape or a bowtie shape. For example, the longitudinal aperture 44 may have a first portion at a top end of the longitudinal aperture 44 having a first width, a second portion at a bottom end of the longitudinal aperture 44 having a second width, and a center portion having a third width that is less than both the first width and the second width. In some embodiments, the part of the longitudinal aperture 44 between the top end of the longitudinal aperture 44 and the bottom end of the longitudinal aperture 44 may be referred to as a transition portion, which transitions from the first width to a narrow width at the center portion to the second width. In an embodiment, the width of the longitudinal aperture 44 may progressively decrease from both longitudinal ends of the longitudinal aperture 44 toward the center portion of the longitudinal aperture 44. For example, the first width may progressively decrease from the top end of the longitudinal aperture 44 to the center portion of the longitudinal aperture 44, and the second width may progressively decrease from the bottom end of the longitudinal aperture 44 to the center portion of the longitudinal aperture 44. In other words, the width of the longitudinal aperture 44 may progressively increase from the center of the longitudinal aperture 44 toward both longitudinal ends of the longitudinal aperture 44, creating a symmetric hourglass or bow-tie shape.

In an embodiment, the nozzle 110 of the vaporizer 100 may be positioned at a center of the wall of the plenum chamber 20 in the Y-axis direction, corresponding to the narrowed center portion of the longitudinal aperture 44. In this configuration, the distance d5 from the top of the plenum plate 40 to a position corresponding to the center of the nozzle 110 may be equal to the distance d6 from the bottom of the plenum plate 40 to the position corresponding to the center of the nozzle 110. In other words, when the nozzle 110 is disposed at a center of the plenum chamber 20, the distances d5 and d6 may satisfy a relationship d5=d6. Additionally, a distance from a top of the longitudinal aperture 44 to the position corresponding to the center of the nozzle 110 may be equal to a distance from the bottom of the longitudinal aperture 44 to the position corresponding to the center of the nozzle 110.

The longitudinal aperture 44 compensates for the higher vapor concentration near the nozzle 110 by restricting vapor flow through the plenum plate 40 at the center portion of the plenum plate 40 that corresponds to the position of the nozzle 110 in the plenum chamber 20, while allowing greater vapor flow through the plenum plate 40 at the top and bottom ends at which vapor concentration in the plenum chamber 20 is lower. This configuration promotes uniform vapor distribution along the longitudinal direction in the plenum chamber 20 and through the plenum plate 40 into the ionization chamber 50, resulting in a more uniform plasma and thus a more uniform ribbon ion beam IB.

In some embodiments, the longitudinal aperture 44 may be symmetric about the center of the longitudinal aperture 44. In other words, the first width at the topmost end may be equal to the second width at the bottommost end, and the longitudinal aperture 44 may narrow symmetrically from both ends of the longitudinal aperture 44 toward the center of the longitudinal aperture 44.

In the example illustrated in FIGS. 25-27, the ion source 1C includes an even number of gas feed chambers 30 (e.g., four gas feed chambers), with the nozzle 110 positioned at the longitudinal center of the plenum chamber 20 and the longitudinal aperture 44 having the hourglass shape or the bowtie shape may provide an optimized vapor distribution. It is noted that FIGS. 25-27 illustrate an example in which the outer lines of the longitudinal aperture 44 are linear from outside corners of the longitudinal aperture 44 to the center of the longitudinal aperture 44, forming a bowtie shape. However, this configuration is only an example and, in some embodiments, the outer lines the longitudinal aperture 44 may have a curved shape to form the hourglass shape.

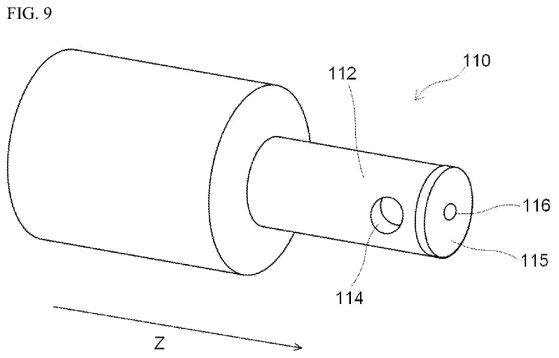

FIG. 9 illustrates an example of a nozzle of a vaporizer of the ion source 1 or the ion source 1′, according to some embodiments. The nozzle 110 may include a pipe 112 and a cap 115 on a distal end of the pipe 112. The pipe 112 may have a plurality of holes 114 formed therein at the distal end of the pipe 112. In an embodiment, two holes 114 may be provided as illustrated in FIG. 9. However, this number is only an example and, in some embodiments, more than two holes 114 may be formed.

In an embodiment, the two holes 114 may be located on opposite sides of the pipe 112. The holes 114 may be located on lateral sides of the pipe 112 (e.g., in the X-axis direction) as illustrated in FIG. 9. However, this location is only an example and, in some embodiments, the holes 114 may be formed in the top and bottom of the pipe 112 (e.g., in the Y-axis direction) (see, e.g., FIG. 4). For example, when the holes 114 are located on the top and bottom of the pipe 112, the vapor may more easily spread out along a longitudinal direction (e.g., the Y-axis direction) in the plenum chamber 20. In an embodiment, a diameter of each of the plurality of holes 114 may be the same. The cap 115 may have a hole 116 formed therein (i.e., in the Z-axis direction). In an embodiment, the diameter of the hole 116 may be smaller than a diameter of each of the holes 114.

In an embodiment, the pipe 112 may extend through the wall of the plenum chamber 20 as described above. As such, a distal portion of the pipe 112 may extend into the plenum chamber 20. In use, a vapor generated from a solid raw material in a crucible (not shown) of the vaporizer 100 may travel through the pipe 112 into the plenum chamber 20 and flow out of the holes 114 and the hole 116 into the plenum chamber 20.

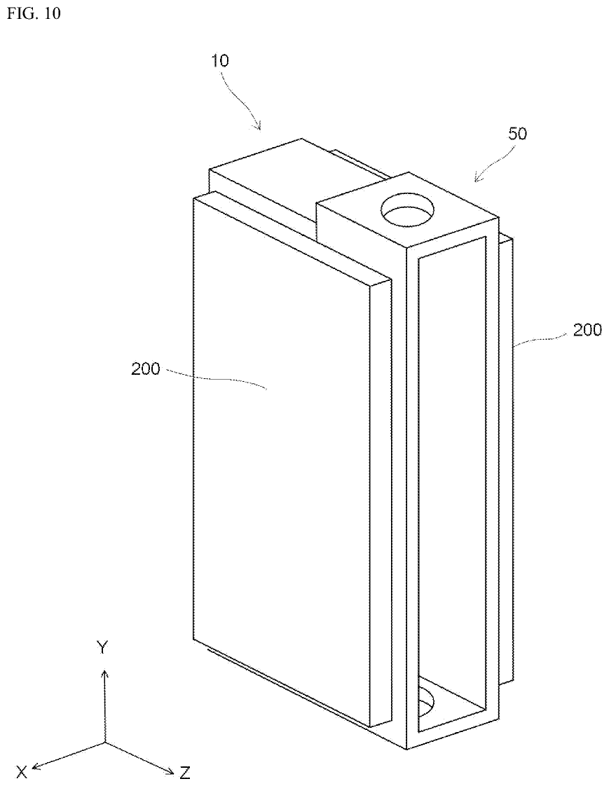

FIG. 10 illustrates an example of a heater of the ion source, according to some embodiments. In an embodiment, a heater 200 may be provided on lateral side surfaces of the plenum 10 and the ionization chamber 50. In an embodiment, the heater 200 may be a block heater as illustrated in FIG. 10. However, embodiments are not limited thereto and, in some embodiments, the heater 200 may be a coil heater. A heater density of the heater 200 at a top and bottom thereof is different than a heater density of the heater 200 at a middle thereof. In other words, the middle of the heater 200 may generate a higher heating temperature than the top and bottom of the heater 200. This is because the cathode 52 and the cathode 55 are provided at the top and the bottom of the ionization chamber 50 and the cathode 52 and the cathode 55 each generate heat. Therefore, for uniform heating, it is not needed to heat the top and bottom ends of the plenum 10 and the ionization chamber 50 as much because the cathode 52 and the cathode 55 provide their own heat. In other words, the heater 200 ensures a uniform temperature of the ionization chamber 50.

In use, the heater 200 helps mitigate condensation of the vapor supplied by the vaporizer 100. For example, in an embodiment, the temperature of the ion source 1 or the ion source 1′ may be very low in comparison with a related art ion source that is used for manufacturing semiconductor devices. As an example, the ion source 1 or the ion source 1′ having a height of about 370 mm to 400 mm and a width of about 60 mm may have a temperature during operation of about 100 °C to about 400 °C. By contrast, the related art ion source that is used for manufacturing semiconductor device may have a height of about 130 mm to 160 mm and a width of about 60 mm and may have a temperature during operation of about 1000 °C to about 1500 °C. The size of the ionization chamber is only one factor that may determine the temperature of the ionization chamber. Other factors may include, for example, an operation method of the ion source, a structure of the cathode in the ionization chamber, etc.

In some embodiments, the heater 200 may be omitted from the lateral side surfaces of the ionization chamber 50 and the heater 200 may only be provided on the lateral side surfaces of the plenum 10. For example, when a temperature of the ionization chamber 50 is higher than a condensation temperature of the vapor, the heater 200 may be omitted from the lateral side surfaces of the ionization chamber 50.

In some embodiments, the heater 200 may be omitted entirely. For example, when the plenum 10 is heated by heat transfer from the ionization chamber 50 and when the temperature of the plenum 10 is higher than the condensation temperature of the vapor, the heater 200 may be omitted from the ion source 1 or the ion source 1′.

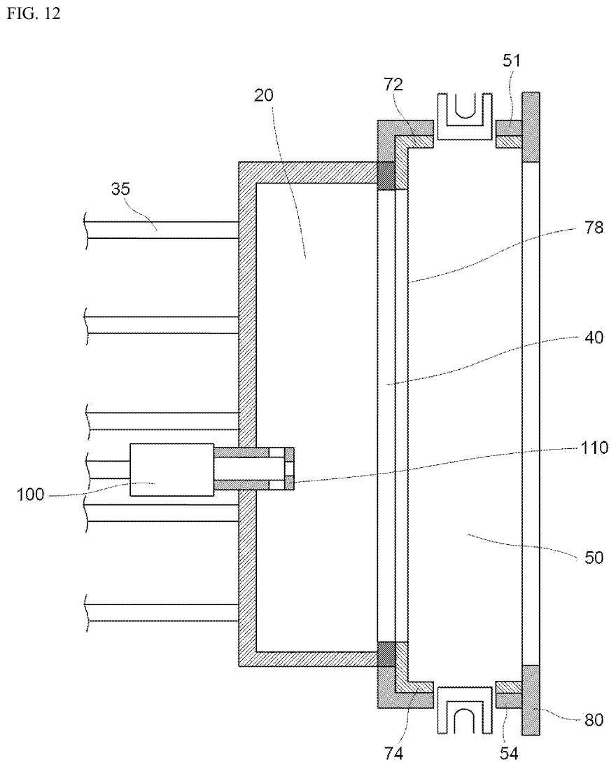

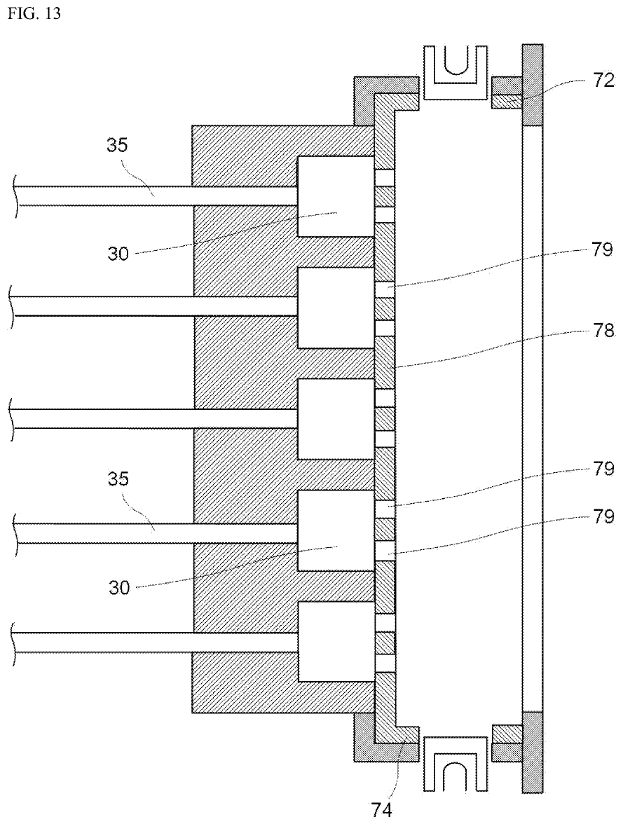

FIGS. 11-13 illustrate a liner of the ion source, according to some embodiments, in which FIG. 11 illustrates the liner when viewed from a Z-axis direction in FIG. 2, FIG. 12 illustrates a cross-sectional view of the liner taken along A-A′ in FIG. 11, and FIG. 13 illustrates a cross-sectional view of the liner taken along B-B′ in FIG. 11.

As described above, in some embodiments, interior walls of the ionization chamber 50 may be covered by the liner 70. In some embodiments, the liner 70 may include the top liner 72, the bottom liner 74, the two side wall liners 76, and the rear liner 78.

As illustrated in FIG. 11, the rear liner 78 may be formed with an opening corresponding to the plenum plate 40 and a plurality of openings 79 for the plurality of gas feed chambers 30. In the example illustrated in FIGS. 11-13, each gas feed chamber 30 is provided with two openings 79 (best seen in FIG. 13). However, embodiments are not limited thereto and, in some embodiments, the rear liner 78 may have one opening 79 or more than two openings 79 for each of the gas feed chambers 30.

In an embodiment, the top liner 72, the bottom liner 74, the two side wall liners 76, and the rear liner 78 may be formed as one single liner 70. However, embodiments are not limited thereto and, in some embodiments, separate liners may be provided.

In an embodiment, the top liner 72, the bottom liner 74, the two side wall liners 76, and the rear liner 78 may each be made of molybdenum. However, this is only an example and, in some embodiments, the top liner 72, the bottom liner 74, the two side wall liners 76, and the rear liner 78 may be made of other materials as long as the material will decrease sputtering onto the walls of the ionization chamber 50.

In some embodiments, the liner 70 may be omitted.

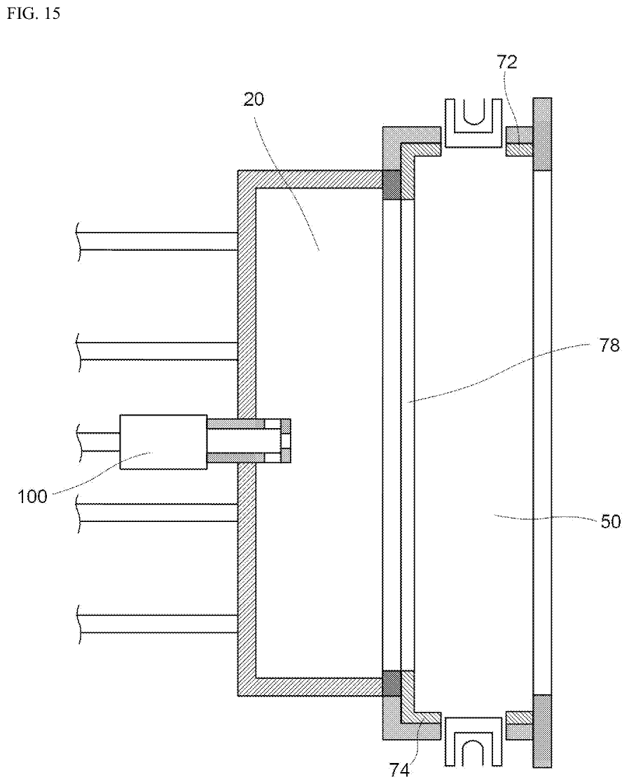

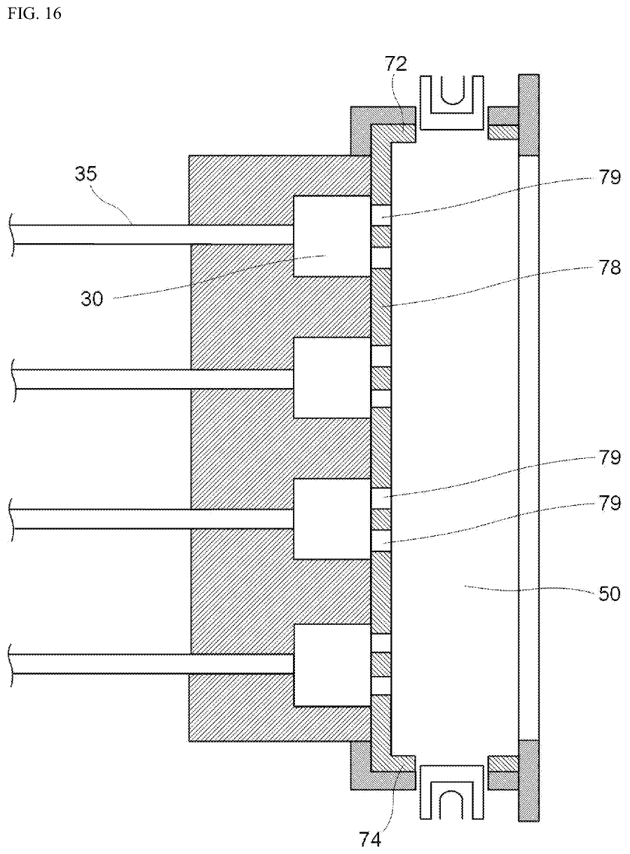

FIGS. 14-16 illustrate a liner of the ion source, according to some embodiments, in which FIG. 14 illustrates the liner when viewed from a Z-axis direction in FIG. 2, FIG. 15 illustrates a cross-sectional view of the liner taken along A-A′ in FIG. 14, and FIG. 16 illustrates a cross-sectional view of the liner taken along B-B′ in FIG. 14. FIGS. 14-16 correspond to FIGS. 13-15 and thus repeated description thereof is omitted for conciseness.

In FIGS. 14-16, an example of the liner 70 as applied to the ion source 1′ of FIGS. 6-8 is illustrated. As with the example illustrated in FIGS. 11-13, the rear liner 78 may include a plurality of openings 79 for the plurality of gas feed chambers 30. In the example illustrated in FIGS. 14-16, each gas feed chamber 30 is provided with two openings 79 (best seen in FIG. 16). However, embodiments are not limited thereto and, in some embodiments, the rear liner 78 may have one opening 79 or more than two openings 79 for each of the gas feed chambers 30.

It should be understood that embodiments are not limited to the various embodiments described above, but various other changes and modifications may be made therein without departing from the spirit and scope thereof as set forth in appended claims.

What is claimed is:

1. An ion source comprising:
a vaporizer comprising a nozzle;
a plenum comprising a plenum chamber having a first wall through which the nozzle extends and a second wall opposite the first wall that comprises a plenum plate; and
an ionization chamber,
wherein the plenum plate separates the plenum chamber from the ionization chamber, and
wherein the plenum plate comprises one or more openings in a longitudinal direction.

2. The ion source according to claim 1, wherein the one or more openings comprise one slit extending in the longitudinal direction.

3. The ion source according to claim 1, wherein the one or more openings comprise a plurality of holes arranged in the longitudinal direction.

4. The ion source according to claim 3, wherein the plurality of holes are arranged in multiple columns.

5. The ion source according to claim 3, wherein the plurality of holes have diameters that progressively increase with distance from a region of the plenum plate that corresponds to a position of the nozzle in the plenum chamber.

6. The ion source according to claim 5, wherein the nozzle is in a center of the plenum chamber in the longitudinal direction.

7. The ion source according to claim 5, wherein the nozzle is below a center of the plenum chamber in the longitudinal direction.

8. The ion source according to claim 3, wherein a distance from a top of the plenum plate to a position of the plenum plate that corresponds to a position of a center of the nozzle in the plenum chamber is greater than a distance from a bottom of the plenum plate to the position of the plenum plate corresponding to the center of the nozzle.

9. The ion source according to claim 8, wherein a number of the plurality of holes provided in the plenum plate above the position corresponding to the center of the nozzle is greater than a number of the plurality of holes provided in the plenum plate below the position corresponding to the center of the nozzle.

10. The ion source according to claim 3, wherein holes located closer to a region of the plenum plate that corresponds to a position of the nozzle have smaller diameters than holes located farther from the region of the plenum plate that corresponds to the position of the nozzle.

11. The ion source according to claim 3, further comprising a liner disposed between the plenum plate and the ionization chamber, the liner comprising a plurality of openings corresponding to the plurality of holes in the plenum plate.

12. The ion source according to claim 11, wherein the liner comprises molybdenum.

13. The ion source according to claim 1, wherein the plenum further comprises a plurality of gas feed chambers respectively coupled to a plurality of gas feed lines, the plurality of gas feed chambers being in fluid communication with an interior of the ionization chamber.

14. The ion source according to claim 1, wherein walls of the ionization chamber comprise graphite or carbon.

15. The ion source according to claim 1, wherein the nozzle comprises a pipe that extends into the interior of the plenum chamber, and a cap that covers a distal end of the pipe,
wherein the pipe comprises two holes in opposite sides of the pipe, each of the two holes having a first diameter, and the cap comprises a single hole having a second diameter smaller than the first diameter.

16. The ion source according to claim 1, wherein:
the one or more openings comprise a longitudinal aperture,
the longitudinal aperture has a first portion having a first width, a second portion having a second width, and a transition portion having a width that gradually changes from the first width to the second width, and
a location of the nozzle in the first wall of the plenum chamber in the longitudinal direction coincides with a center of the transition portion in the longitudinal aperture in the longitudinal direction.

17. The ion source according to claim 1, wherein the one or more openings comprise a longitudinal aperture having an hourglass shape, in which a width of the longitudinal aperture gradually increases with distance from a center of the plenum plate in the longitudinal direction.

18. The ion source according to claim 1, wherein the one or more openings comprise a longitudinal aperture having a bowtie shape, in which a width of the longitudinal aperture gradually increases with distance from a center of the plenum plate in the longitudinal direction.

19. An ion source comprising:
a vaporizer comprising a nozzle;
a plenum chamber having a first wall through which the nozzle extends and a second wall opposite to the first wall, the first wall and the second wall defining an interior space in which a vapor from the vaporizer spreads out from the nozzle; and
an ionization chamber,
wherein a plenum plate forms the second wall of the plenum chamber and separates the plenum chamber from the ionization chamber, and
wherein the plenum plate comprises one or more openings in a longitudinal direction through which the plenum chamber is in fluid communication with the ionization chamber.

20. The ion source according to claim 19, wherein the one or more openings comprise:
one slit extending in the longitudinal direction;
a plurality of holes arranged in the longitudinal direction and having diameters that progressively increase with distance from a region of the plenum plate that corresponds to a position of the nozzle in the plenum chamber;
a longitudinal aperture having an hourglass shape, in which a width of the longitudinal aperture gradually increases with distance from a center of the plenum plate in the longitudinal direction; or
a longitudinal aperture having a bowtie shape, in which a width of the longitudinal aperture gradually increases with distance from the center of the plenum plate in the longitudinal direction.
